(19) United States
(12) Patent Application Publication
(10) Pub. No.: US 2007/0280872 A1
(43) Pub. Date: Dec. 6, 2007

(54) Method of growing gallium nitride crystal and gallium nitride substrate

(75) Inventors: Takuji Okahisa, Hyogo (JP); Kensaku Motoki, Hyogo (JP); Koji Uematsu, Hyogo (JP); Seiji Nakahata, Hyogo (JP); Ryu Hirota, Hyogo (JP); Hideyuki Ijiri, Hyogo (JP); Hitoshi Kasai, Hyogo (JP); Shunsuke Fujita, Hyogo (JP); Fumitaka Sato, Hyogo (JP); Toru Matsuoka, Hyogo (JP)

Correspondence Address: MCDERMOTT WILL & EMERY LLP, 600 13TH STREET, N.W., WASHINGTON, DC, 20005-3096, US

(73) Assignee: SUMITOMO ELECTRIC INDUSTRIES, LTD.

(21) Appl. No.: 11/806,888

(22) Filed: Jun. 5, 2007

Related U.S. Application Data
(63) Continuation-in-part of application No. 10/933,291, filed on Sep. 3, 2004.
Application No. 10/933,291 is a continuation-in-part of application No. 10/700,495, filed on Nov. 5, 2003, now Pat. No. 7,112,826.
Application No. 10/700,495 is a division of application No. 10/246,559, filed on Sep. 19, 2002, now Pat. No. 6,667,184.
(63) Continuation-in-part of application No. 10/936,512, filed on Sep. 9, 2004.
Application No. 10/936,512 is a continuation-in-part of application No. 10/265,719, filed on Oct. 8, 2002, now Pat. No. 7,087,114.

(30) Foreign Application Priority Data
Jun. 8, 2006 (JP) 159880/2006
Sep. 19, 2001 (JP) 2001-284323
Aug. 8, 2002 (JP) 2002-230925
Oct. 9, 2001 (JP) 2001-311018
Sep. 17, 2002 (JP) 2002-269387

(51) Int. Cl. C30B 19/00; C01B 21/06; H01L 21/322

(52) U.S. Cl. 423/409; 117/2

(57) ABSTRACT

The GaN facet growth method produces defect accumulating regions H on masks by forming a dotmask or a stripemask on an undersubstrate, growing GaN in a reaction furnace in vapor phase, inducing GaN crystals on exposed parts without covering the masks, inviting facets starting from verges of the masks and producing defect accumulating regions H on the mask. The defect accumulating regions H have four versions, that is, non (O), polycrystal (P), c-axis inclining single crystal (A) and orientation inversion (J). The best is the orientation inversion region (J). A sign of occurrence of the orientation inversion regions (J) is beaks of inversion orientation appearing on facets. GaN is grown on a masked undersubstrate by supplying a carbon material at a hydrocarbon partial pressure of 10 Pa to 5 kPa for 0.5 hour to 2 hour by an HVPE facet growth method without burying facets.

### RELATED APPLICATION

This application is a Continuation-In-Part (CIP) of application Ser. No. 10/933,291 filed on Sep. 3, 2004 and application Ser. No. 10/936,512 filed on Sep. 9, 2004.

This application claims priority to Japanese Patent Application No.159880/2006 filed on Jun. 8, 2006.

### FIELD OF THE INVENTION

The next generation large capacity photodiscs make use of GaN type blue/violet lasers. Practical production of the GaN type blue/violet lasers requires high quality GaN substrates. This invention relates to a method of growing GaN crystals in order to produce high quality GaN substrates.

GaN type semiconductor lasers of a 405 nm wavelength are promised to be used for reading out the high density photodiscs. At present, blue/violet LEDs (Light Emitting Diodes) are produced by piling GaN, InGaN, etc. films on sapphire (Al₂O₃) substrates (wafers). Sapphire is rather different from GaN in lattice constant. Lattice misfit induces high density defects in the GaN, InGaN films piled on sapphire wafers. Current density is small in LEDs. Due to the small current density, defects are not proliferated in LEDs. On-sapphire GaN type LEDs are prevalent. Current density is far large in laser diodes (LDs).

The large current density proliferates dislocations in LDs. Sapphire substrates are inappropriate for LDs, because high current density multiplicates dislocations and degenerates the LDs. Unlike LEDs, on-sapphire blue/violet GaN LDs have not been put into practice.

There is no material which has a lattice constant sufficiently close to GaN. It turns out that the substrates on which GaN films are safely grown should be GaN substrates. Realization of GaN type blue/violet lasers ardently requires high quality GaN substrates with low dislocation density.

Crystal growth of GaN is very difficult. Heating GaN does not make a melt of GaN. No GaN melt can be obtained. Conventional liquid phase crystal growth methods are inapplicable to GaN crystal growth. Many trials have been done for growing GaN substrate crystals from vapor phase by supplying gaseous materials. Various attempts have been done for growing GaN crystals in order to produce practically large sized GaN substrate wafers.

The inventors of the present invention have contrived a method of forming masks on a foreign material undersubstrate, growing a GaN film crystal on the masked undersubstrate, eliminating the undersubstrate and obtaining a GaN freestanding crystal.

(1) WO99/23693 which was invented by the inventors of the present invention proposed a method of forming a stripe mask with parallel stripes or a dot mask with uniformly distributing isolated round dots on a GaAs undersubstrate, growing a thick GaN crystal on the mask-covered GaAs undersubstrate, removing the GaAs undersubstrate and obtaining a freestanding GaN crystal substrate. The masks have wider covered parts and narrower exposed parts (windows, holes). Namely the masks are covered part prevailing masks. GaN crystal nuclei happen only on exposed parts at the initial stage. Masks prevent nuclei from occurring. GaN nuclei dilate, unite , make films and produce cones on the exposed parts. GaN grains overstep the window margins onto masks. GaN crystals grow on the masks in horizontal directions. Dislocations expand also in the horizontal directions on the masks. Then horizontally expanding crystals collide together on the masks. Then the direction of growth changes from the horizontal direction to the vertical direction. After. the collision, the GaN crystals grow upward. Dislocations turn the direction. Dislocations expand in the vertical direction. Twice changes of extending directions reduce dislocations at an early stage of growth. Then GaN grows in the vertical direction with a C-plane surface.

The method capable of decreasing dislocations by changing the directions of growth twice is called an Epitaxial Lateral Overgrowth (ELO) method. A freestanding GaN crystal enjoying a low dislocation density is obtained by eliminating the GaAs undersubstrate. (1) WO99/23693 proposed a method of growing a thick GaN crystal on the obtained GaN undersubstrate in vapor phase, slicing the thick GaN crystal several times in the planes vertical to the growth direction and obtaining a plurality of GaN wafers. There are an MOCVD method, an MOC method, an HVPE method and a sublimation method for vapor phase growth methods of GaN. (1) WO99/23693 advocated the HVPE (Hydride Vapor Phase Epitaxy) method because the HVPE has an advantage of a high growing speed. Considerably high density of dislocations accompany the GaN crystals made by the ELO/HVPE method. The GaN crystals produced by (1) WO99/23693 based on the ELO/HVPE are high defect density crystals of low quality. When GaN type photodevices are made on a high defect density low quality GaN substrate, the devices are also bad, malfunctioning photodevices. Production of high quality photodevices requires low defect density high quality GaN substrates. In particular, mass production of GaN photodevices demands high quality GaN wafers with low dislocation density in wide regions. (2) Japanese Patent Laying Open No.2001-102307 which was invented by the inventor of the present invention proposed a new method of GaN growth effective in reducing dislocations on GaN substrates.

The method proposed by (2) Japanese Patent Laying Open No.2001-102307 decreases dislocations by growing a thick GaN crystal, gathering dislocations from other regions into definite regions and lowering dislocation density at the regions other than the definite regions.

(2) Japanese Patent Laying Open No.2001-102307 mentioned a method of growing a GaN crystal, forming a three dimensional facet structure, for example, inverse-hexagon cone pits consisting of facets in the growing GaN crystal, maintaining the facet structure without burying the facets till the end of growth, gathering dislocations from other regions into the facet pits and lowering the defect density in other regions. FIG. 1(a) and FIG. 1(b) show a section of a GaN crystal 4 having a facet pit 5 shaped into an inverse hexagonal cone. The surface of the GaN crystal is not an entire smooth surface but a flat surface and facet pits 5 distributing on the flat surface. The flat surface 7 is a C-plane. The pits 5 are sometimes hexagonal cones and at other times dodecagonal cones. In a hexagonal pit, facets meets with neighboring ones at 120 degrees. Neighboring facets 6 and 6 are in contact with each other at a boundary 8. The boundaries 8 converge at a pit bottom 9. Bottom ends of facets 6 assemble at the pit bottom 9 which is a converging point of the boundaries 8.

Crystal growth progresses in the directions of normals which are half lines vertical to the planes. An average growth direction is an upward direction along a c-axis. The flat C-plane 7 grows in the upward direction (c-axis direction). Facets grow in slanting directions normal to the facets. Namely the growth direction of a facet 6 is the direction of the normal standing on the facet 6. An inclination angle of a facet to the C-plane is denoted by “Θ”. The facet growth mode does not bury facet pits. The growth without burying pits means that the upper C-plane growth speed u is different from the facet growth speed v. Maintenance of the constant facet pits requires anisotropic growth speeds indicated by v=u cos Θ. The facet growth speed v is slower than the upper C-plane growth speed u.

Dislocations D extend in parallel to the growing direction. Dislocations which exist on a facet move toward the nearest boundary with the crystal growth. v<u. The facet growth is slower than the C-plane growth in speed. The extension speed of a dislocation is equal to the growth speed. The dislocation which once reaches the boundary 8 is fixed to the boundary 8 afterward. Since v<u, the dislocation descends along the boundary 8 and arrives at the pit bottom 9. Dislocations on the facets are assembled via boundaries to the bottom 9 by the facet growth. Thus planar defect assembling regions 10 are produced just below the boundaries 8 by the dislocations reaching the boundaries, as shown in FIG. 1(b). Linear defect assembling bundles 11 are made just below the bottom 9 by the dislocations arriving at the boundaries and falling to the bottom 9. Since facets initially lying on the facets are gathered into the planar defect assembling regions 10 and the linear defect assembling bundles 11, the facets 6 become nearly free from dislocations. Since the facets are low dislocation density, dislocations lying on the C-planes 7 are pulled into the facets 6. The dislocations D on the facets are moved to the boundaries 8 by the facet growth. When the pits exist in high density, dislocations are swept and gathered to the planar defect assembling regions 10 below the boundaries 8 and the linear defect assembling bundles 11 below the bottom 9. Dislocations in other regions are reduced. Keeping the facets pits without burying pits 5 enables the facets pit to maintain the dislocation reduction effect to the last of growth.

FIG. 2 is a plan view of a pit for showing the dislocation reduction effect of facet growth method. The crystal growing direction on a facet 6 is parallel to the normal standing on the facet 6 when the facet 6 is maintained. Dislocations lying on the facet 6 expand also in the normal direction parallel with the growth direction. FIG. 2 demonstrates dislocations D moving in the same direction as the growth direction on the facets 6. FIG. 2 shows growth directions and dislocation extensions as projections on a horizontal plane. In the plan view dislocations move in the direction of the inclination of the facet 6. As the GaN crystal grows, dislocations D come closer to boundaries 8 and arrive at the boundaries. When the dislocations D reach the boundaries, the dislocations turn the extension direction and move inward along the boundaries 8. An inward movement denotes a relative downward movement in the GaN crystal growing on the facets. In reality, dislocations extend not downward but upward. Since v<u, dislocations relatively sink down in comparison with a faster growing GaN crystal. Some dislocations D, which have failed in arriving at the bottom, make planar defect assemblies 10 below the boundaries 8. Other dislocations D, which have arrived at the bottom 9 of the pit 5, make linear defect assembling bundles 11 below the bottom 9. Since dislocations are gathered to the defect assemblies 10 and 11, other parts become low defect density.

However, problems have been found in the facet growth method capable of reducing dislocations by making use of the facet growth.

Problem (1): When the crystal grows thicker and thicker and dislocations D are gathered more and more at the defect assembling bundles 11, the dislocations D are liable to disperse from the bundles 11. Release of dislocations makes hazy dispersion around the defect assembling bundles 11. Release of dislocations is explained by referring to FIGS. 3(1) and 3(2). FIG. 3(1) shows a section of a slim linear defect assembling bundle 11 formed at a bottom 9 of a pit 5 at an early stage of growth. FIG. 3(2) shows hazy dispersion 13 of dislocations releasing from the linear defect assembling bundle 11. Occurrence of the hazy dispersion 13 signifies a poor power of the linear defect assembling bundle 11 for arresting dislocations D.

Problem (2): The places of the linear defect assembling bundles 11 are accidentally determined. The linear defect assembling bundles 11 distribute at random. The places of the bundles 11 cannot be predetermined. To say other words, the places of defect assembling bundles 11 are uncontrollable.

Problem (2) derives from the fact that facet pits happen at arbitrary points accidentally determined and facet pits distribute at random. It is preferable to determine the positions generating facet pits before the growth. Problem (1) should be conquered by building barriers for preventing once gathered dislocations from dispersing again.

The inventors of the present invention have made the following contrivance for solving the two problems (1) and (2).

The inventors have noticed that gathered dislocations stay temporarily in the bundles at the bottom 9 of the hexagonal cone pits 5, the dislocations do not perish and dislocations have a tendency of releasing from the bundles and the hazy dispersion 13 of once arrested dislocations occurs.

The inventors have hit on a new idea of adding an annihilating/accumulating device to the defect accumulating bundles. FIG. 4(1) and FIG. 4(2) demonstrate the annihilating/accumulating device produced at the bottom of a facet pit. Masks 23 which are made of a material capable of prohibiting GaN from epitaxial growing are formed in a regular distribution on an undersubstrate 21. At the initial stage, no nuclei occur on the masked parts and crystal growth begins only on exposed parts. GaN crystals 24 having a C-plane surface 27 grow on the exposed parts.

The masks 23 prevent GaN from growing. Crystal growth on the masks 23 delays. Crystal grows on the exposed parts, leaving the masks uncovered. Facets 26 starting from edges of the masks 23 and pits 25 consisting of the facets 26 are produced. The facets 26 and the pits 25 are not buried but are maintained until the end of the crystal growth. Crystal growth sweeps dislocations along the facets 26 and guides dislocations into pit bottoms 29. The bottoms 29 of the pits coincide with the masks. Dislocations D are gathered above the masks 23 below the pit bottoms 29. On-mask regions gathering dislocations become defect accumulating regions H, which follow the bottoms 29 of the pits 25. A defect accumulating region H consists of a grain boundary K and a core S. H=S+K. The facet growth method succeeds in producing defect accumulating regions H enclosed by the grain boundary K as a dislocation annihilation/accommodation device by preparing masks on an undersubstrate. The mask 23, the defect accumulating regions H and the pit bottom 29 align in the vertical direction. The masks 23 determine the positions of defect accumulating regions H and pit bottoms 29. The portions below the facets on exposed parts are low defect single crystal regions Z. The portions below the C-plane on the exposed parts are called “C-plane growth regions Y.”

Dislocations assemble on the defect accumulating regions H. Each of the defect accumulating regions H has a definite width and is enclosed by a grain boundary K. The boundaries K prevent dislocations from releasing out of the defect accumulating regions H. The grain boundaries K have a function of annihilating dislocations. The core S is an inner part encapsulated by the boundary K. The core S has a function of accommodating and annihilating dislocations. Thus the defect accumulating region H composed of S and K becomes a dislocation annihilating/accommodating device. It is important to build up the defect accumulating regions H composed of grain boundaries K and cores S having the annihilating/accommodating function by masks. Progress of crystal growth changes the section of the facet growing crystal from FIG. 4(1) to FIG. 4.(2). Dislocations are not released from H, since dislocations are firmly arrested in H. The same state is kept until the end of the growth. Hazy dispersion of dislocations is forbidden. The facet growth solves the difficulty with the hazy dispersion of dislocations as explained in FIG. 3(2). The substance of the defect accumulating region H was not fully understood at the beginning of the facet growth. The defect accumulating region H has no constant structure but different structures. One defect accumulating region is a polycrystal P and another defect accumulating region H is a c-axis slanting single crystal A. Another defect accumulating region H is a c-axis inversion single crystal J. Sometimes no defect accumulating region occurs (O). What structure the defect accumulating region takes depends upon growth conditions.

The best candidate among O, P, A, and J is the c-axis inversion single crystal J which has a c-axis ([0001] direction) inverse to the surrounding regions Z and Y. In the case (H=J), the defect accumulating region H has a polarity inverse to the surrounding crystal Z. A definite clear grain boundary K is generated around the defect accumulating region H.

The grain boundary K has a strong function of attracting, annihilating and arresting dislocations.

When a defect accumulating region H becomes a polycrystal P or a c-axis inclining single crystal A, a clear definite grain boundary K does not occur. The defect accumulating region with A or P has a weak, insufficient power of annihilating and accommodating dislocations.

The surrounding regions are classified into two different regions. A part grown under a facet on an exposed part is called a “low defect density single crystal region Z”.

Another part grown under a C-plane on an exposed part is called a “C-plane growth region Y”. Both Z and Y are low defect density single crystals having the same orientation. But Z and Y have different electric properties. The C-plane growth regions Y have higher conductivity. The low defect density single crystal regions Z have lower conductivity.

The low defect density single crystals Z and the C-plane growth regions Y are single crystals with an upward c-axis ([0001]). The defect accumulating regions H of the polarity inversion regions J are single crystals with a downward c-axis ([000-1]). Since the orientation is inverse, a continual grain boundary K stably occurs between H and Z. The grain boundary K has a strong power of annihilating and arresting dislocations. Occurrence of K between H and Z is a profitable property. An inner core S and an outer space are definitely discerned by the grain boundary K.

The inversion c-axis region J as a defect accumulating region H is the most effective in lowering dislocation density.

The growth speed of the orientation inversion defect accumulating regions (H, J) is lower than Z and Y. The orientation inversion defect accumulating regions H make pits or valleys. Therefore the defect accumulating regions H can stably stay at the bottoms of pits or grooves.

The grain boundaries K around the defect accumulating region H effectively arrest and annihilate dislocations and prohibits once-arrested dislocations from escaping. No hazy dispersion of dislocations occurs. A low defect density GaN substrate crystal with dislocations arrested in the defect accumulating regions H is obtained.

It is possible to produce and fix defect accumulating regions H at arbitrary spots on an undersubstrate with a mask. Defect accumulating regions H do not occur accidentally and randomly but are generated on predetermined spots or lines on an undersubstrate. The predetermined spots/lines mean the masked spots/lines. The property enables the facet growth to make high quality GaN crystals with regularly aligning defect accumulating regions H on predetermined spots or lines.

There are several different shapes of the defect accumulating region H. For example, isolated dot-like defect accumulating regions can be produced. Stripe parallel defect accumulating regions can be also made. Another shape of defect accumulating regions can be prepared. (3) Japanese Patent Laying Open No.2003-165799 demonstrates regularly distributing isolated defect accumulating regions. FIG. 10(1) is a plan view for showing an example of a dotmask which is composed of regularly aligning isolated mask dots M on an undersubstrate U. low defect density GaN crystals are grown on exposed parts. The mask dots M make defect accumulating regions H thereon. Facet pits having a bottom composed of a defect accumulating region H are generated in a growing GaN crystal. Parts under the facets on exposed parts become low defect density single crystal regions Z. Other parts out of the facets on exposed parts become C-plane growth regions Y. FIG. 6(2) is a perspective view of a portion of a GaN crystal grown on a dotmasked undersubstrate U. The GaN crystal has a wide flat C-plane growth region Y. Many polygonal pits composed of facets F occur. The pit bottoms exist just above the mask dots. FIG. 10.(2) is a plan view of a flat GaN substrate crystal which is made by eliminating the undersubstrate from the GaN crystal grown on a dotmasked undersubstrate (M2U), obtaining a freestanding as-cut GaN wafer, grinding the GaN as-cut wafer and polishing the as-ground GaN wafer into a GaN mirror wafer. On-mask parts become defect accumulating regions H. Low defect density single crystal regions Z and C-growth region Y enclose the defect accumulating regions H. A concentric structure (YZH) appears on the dotmask-grown GaN substrate crystal.

Another alternative of masks is a stripemask having a plurality of parallel mask stripes. Use of a stripemask can make stripe distributing defect accumulating regions H in GaN crystals. (4) Japanese Patent Laying Open No.2003-183100 proposed a GaN crystal having stripe-distributing defect accumulating regions H. FIG. 8 (1) shows an example of a stripemask pattern. Many parallel mask stripes with a width s are aligned at a pitch p on an undersubstrate U. An exposed part has a width (p-s). A facet growth method grows a GaN crystal on the stripemasked undersubstrate. FIG. 6(1) exhibits roof-shaped GaN crystals grown on the stripemasked undersubstrate. Parallel mountains composed of low defect density single crystal regions Z are produced upon exposed parts. Slopes of the mountains are facets F. V-valleys appear above the mask stripes M. Defect accumulating regions H are produced upon the stripes M. Bottoms of the V-valleys correspond to the stripes M. No C-plane growth regions Y appear in the example of FIG. 6(1). Otherwise, C-plane growth regions Y appear under flat C-planes on exposed parts. A flat smooth GaN substrate can be obtained by eliminating the undersubstrate from the roof-shaped GaN crystal of FIG. 6(1), grinding the roof-shaped GaN crystal into a flat GaN wafer and polishing the GaN wafer. FIG. 8(2) is a plan view of the polished GaN wafer. The GaN substrate with Ys has a parallel HZYZHZYZ . . . structure. The GaN substrate without Y has a parallel HZHZHZ . . . structure.

FIG. 5(1), FIG. 5(2) and FIG. 5(3) demonstrate steps of a facet growth method using a stripemask. FIG. 5(1) shows a part of an undersubstrate U on which a stripe mask consisting of plenty of parallel mask stripes M is formed. The mask stripes extend in the direction vertical to the sheet. Parts covered with the stripes are called “masked parts”. Other parts not covered with the stripes are called “exposed parts”. The exposed part and the masked part have different functions. GaN is grown on the masked undersubstrate (MU) in vapor phase. Exposed parts allow GaN to make GaN nuclei and grow GaN crystals thereon. Masked parts prohibit GaN from making nuclei at the initial step. GaN crystals having a C-plane surface are grown on the exposed parts (FIG. 5(2)). The masked parts are still uncovered. Extension of GaN crystals is stopped at the sides of the mask stripes M. Slants of crystals are produced near the verges of the masks M. The slants are facets F. FIG. 5(2) exhibits a vacant stripe M, GaN crystals covering the exposed parts and facets F starting from the sides to the top of the GaN crystals.

At a later stage, GaN crystals are grown also above the masked parts. The above-mask space has a cavity because the growth on the masks is delayed. The crystals on the masks are defect accumulating regions H consisting of inversion c-axis crystals. Milder inclining facets F′ and F′ appear on the top of the defect accumulating regions h. The inclination of F′ is identical to the inclination of the upper slants of the beaks Q in FIG. 7(3) and FIG. 7(4). Since the defect accumulating regions H grow upon unified beaks Q, the orientation of the defect accumulating regions H is identical to the beaks Q. GaN crystals following the facets F on exposed parts are low defect density and single crystals. Thus the portions under the facets on the exposed parts are named low defect density single crystal regions Z. The other portions growing under the C-plane surface are also low defect density and single crystals. The portions are named C-plane growth regions Y for discriminating from Z. Grain boundaries K are formed between the defect accumulating regions H and the low defect density single crystal regions Z. The boundaries between different inclination angle facets F and F′ coincide with the grain boundaries K.

In the stripemask case having plural parallel mask stripes, defect accumulating regions H produce parallel deep valleys coinciding with the stripes. Exposed parts between neighboring masks become low defect density single crystal regions Z or C-plane growth regions Y. Zs and Ys produce parallel hills. The stripemask produces a crystal structure with repeating sets of parallel hills and valleys. C-plane growth regions Y sometimes do not happen. When no C-plane growth regions Y appear, the crystal structure has sharp hills. When C-plane growth regions Y happen, the crystal structure has blunt hills with flat tops.

Similar regions to H, Y and Z occur in the case of the dotmask case, which consists of regularly distributing isolated mask dots. Isolated pits consisting of facets F are formed around the isolated mask dots M. The bottom of the pit coincides with the mask dots M. Portions beneath the facets F on exposed parts become low defect density single crystal regions Z. The other portions under the C-plane on exposed parts become C-plane growth regions Y. Both the low defect density single crystal regions Z and the C-plane growth regions Y are low defect density single crystals having the same orientation.

The parts above the dots M become defect accumulating regions H in both the stripemask case and dotmask case. The defect accumulating region is a polycrystal P, a c-axis slanting single crystal A or a c-axis inversion single crystal J. Sometimes no defect accumulating region H is yielded on a mask (O). The portion above a mask has four alternatives O, A, P and J. Namely H=O, A, P or J.

When c-axis inversion regions (=orientation inversion) J are produced (H=J) on masks, the defect accumulating regions H have Ga-planes and N-planes inverse to the other parts (Z, Y). The c-axes of the defect accumulating regions H are inverse to the c-axes of the other parts (Z, Y). The inventors of the present invention call the orientation inversion single crystal region as a polarity inversion region. Thus the polarity inversion region, the c-axis inversion region and the orientation inversion region are synonyms.

The interfaces between H and Z are grain boundaries K. Milder facets F′ and F′ appear on the defect accumulating region H in the case of H=J. The GaN crystal grown on a dotmasked undersubstrate has plenty of isolated pits corresponding to the mask dots on a C-plane surface. The GaN crystal grown on a stripemasked undersubstrate has a plurality of parallel hills and valleys corresponding to the mask stripes. In the dotmask case, the defect accumulating regions H are isolated closed regions consisting of facets F. The facets F are mainly {11-22} planes and {1-101} planes. In the stripemask case, the defect accumulating regions H are parallel extending regions. The facets are determined by the direction of the stripemask. Masks M are seeds of the defect accumulating regions H.

Formation of seeds (masks) on an undersubstrate determines the positions on which defect accumulating regions H will grow. Through the decision of positions of Hs, the positions of both low defect density single crystal regions Z and C-plane growth regions Y are determined by the seeds (masks). The convenient property of the mask facet growth solves the aforementioned problem (2) that the positions of the defect accumulating regions H are not predetermined.

The orientation (polarity) inversion defect accumulating region H produces a clear, definite grain boundary K. The grain boundary K arrests dislocations firmly, prohibiting dislocations from passing through. The polarity inversion defect accumulating region H suppresses the hazy release of dislocations. The positions of making defect accumulating regions H become controllable by forming masks on an undersubstrate as seeds of Hs.

Mask positions can definitely control the positions of defect accumulating regions H, low defect density single crystal regions Z and C-plane growth regions Y. It turns out that a defect accumulating region H cannot always make a grain boundary K. Defect accumulating regions H occur on masks. But the defect accumulating region H is not always a c-axis 180 degree inversion, i.e. an orientation (polarity) inversion region J. Sometimes an on-mask defect accumulating region H becomes a polycrystal P. At other times.another on-mask defect accumulating region H becomes a c-axis slanting single crystal A which has an inclining c-axis different from the c-axis of the surrounding regions Z and Y. Sometimes no defect accumulating region H happens (O). On-mask regions take four different versions O, A, P and J.

When the defect accumulating region H is a polycrystal P, some of grains have orientation similar to the surrounding regions (Z, Y) and a continual, clear grain boundary K does not occur around the polycrystal defect accumulating region P. When the defect accumulating region H is a c-axis inclining single crystal A, some parts of A have orientations similar to the surroundings Z and Y and a continual definite boundary K is not generated. Building a clear, continual grain boundary K requires an on-mask 180 degree inversion c-axis region J.

When an orientation inversion region J is produced on a mask, any part of the region J has crystal lattice orientation different from the surroundings Z and a definite powerful grain boundary is produced around the orientation inversion region J. The grain boundary K has a strong power of arresting dislocations. Without a definite grain boundary K, the defect accumulating region H has a weak power of arresting, annihilating and accommodating dislocations. Strong dislocation arrest, annihilation and accommodation ardently require the occurrence of orientation inversion defect accumulating regions J on masks. A purpose of the present invention is to provide a reliable method of making 180 degree c-axis rotation polarity inversion regions J on masks as defect accumulating regions H.

The best defect accumulating region H is an inversion region J. A purpose of the present invention is to build polarity inversion regions J on masked parts for a certainty.

(1) Seeds (masks) M, which are a material capable of inhibiting GaN from epitaxially growing thereon, are formed upon the positions on which defect accumulating regions H shall be grown. Here the seed mean a seed of a defect accumulating region H. The seed is a synonym for a mask. FIG. 7(1) demonstrates a section of a mask M formed on an undersubstrate U. FIG. 7(1) shows a part of the undersubstrate U having only one mask. In reality, plenty of mask stripes or dots M are formed on U. The part covered with the mask M is called a “covered (masked) part”. The other part not covered with the mask is called an “exposed (unmasked) part.”

(2) Gallium nitride (GaN) is grown on the masked undersubstrate U in vapor phase. Exposed parts facilitate production of crystal nuclei. Covered parts prevent nuclei from occurring. GaN crystal growth starts only on the exposed parts. Growing crystal has a C-plane top surface on the exposed parts. Progress of crystal growth is forbidden at the ends of the masks M. At an early stage, crystals do not overrun the sides of the masks M. The sides stop horizontal extension of the crystal growth. Slants starting from the sides of the mask M appear (FIG. 7(2)). The slants are facets F which are not a C-plane. In many cases, the facets are {11-22} planes. Stripe masks produce parallel, linear facets F which extend in the direction vertical to the paper. Dot masks make plenty of isolated hexagonal pits composed of facets. The stripe mask and the dot mask are similar in the growing steps following the formation of facets. Therefore the case of the stripe mask is described hereafter.

(3) Small beaks Q, which have inverse c-axes and inverse orientations, appear at middle points on the slanting facets F which have feet stopped at the ends of masks M. The beaks Q extend in horizontal directions. FIG. 7(3) shows the beaks Q. A beak Q has an upper slant milder than the facet F and a steep lower slant. Examination has clarified that the beak Q has orientation different at 180 degrees from the surrounding regions. Namely the beaks Q are polarity inverse regions.

(4) Progress of crystal growth increases the number of beaks Q appearing on the slanting facets F. Beaks Q dilate. Tiny beaks are unified into a large beak on each of the facets F. The beaks Q inward expand and cover the mask M with a gap.

(5) The beaks Q have inverse orientation. The beak has an upper facet F′ whose inclination angle is smaller than the following facet F. The upper facets F′ is one of the lower inclination angle facets {11-2-6}, {11-2-5} and so forth. The lower facet of the beak Q is a facet steeper than F′.

The beaks Q dilate in the vertical and horizontal directions. Tips of the paired beaks Q collide with together above the mask M. The beaks Q are unified. A bridge is formed by the coupled beaks above the mask M. Crystals having the same inverse orientation grow on the bridged beaks Q and Q. Inverse crystal buries the lower gap between the mask and the bridge. The crystal above the beaks Q has not horizontally grown from the facets F but has vertically grown on the inverse orientation beaks Q. The crystal above the mask has the orientation inverse to the orientation of the surrounding crystals Z and Y.

(7) The middle portion on the collision tips makes a lattice-misfitting boundary K′ therebetween and grows thick. The middle boundary K′ is different from the H/Z boundary K. The inverse orientation beaks Q become defect accumulating regions H.

(8) When the crystal grows further (FIG. 7(5)), dislocations in the GaN crystal are gathered onto the unified beaks above the masks M by slantingly growing facets F. Upward extension of the beaks makes defect accumulating regions H above the masks M. A part of the gathered dislocations vanish at the grain boundaries K or the cores S of the defect accumulating regions H. The rest are arrested and accumulated in the grain boundaries K and the cores S. The defect accumulating regions deprive dislocations of other parts. The parts under the facets F become low dislocation single crystal regions Z.

The above processes produce defect accumulating regions H as orientation inversion regions J. Production of polarity inversion regions J on masks requires to generate beaks Q on all the facets (for example, {11-22} facets) as shown in FIG. 7(3). Stable and allover formation of beaks Q on facets is important for inducing the polarity inversion regions J. Unless stable and allover beaks are produced, defect accumulating regions H on masks would not become orientation inversion regions J. In the case, on-mask regions H cannot strongly attract dislocations from the surrounding regions and cannot annihilate the dislocations. Dislocations are dispersed into the neighboring regions. No low defect single crystal regions Z occur under the facets.

Vapor phase facet growth on a masked undersubstrate cannot necessarily make polarity inversion regions J on masks. Formation of the beaks Q on facets is indispensable to make orientation inversion regions J. However, it is not easy to produce stable orientation inversion beaks Q on all the facets slantingly expanding from the sides of masks.

This invention decreases dislocations by facet growth. This method can be called a “facet growth method.” The facet growth method is entirely different from the well-known epitaxial lateral overgrowth (ELO) method which relies upon masks for reducing dislocations. The facet growth method completely differs from the ELO. But the facet growth method has a possibility of being confused with the ELO, because both the facet growth method and the ELO make use of masks for decreasing dislocations. Several different points are explained for avoiding the confusion of the facet growth method with the ELO.

(a) The ELO employs a wide mask. The ELO prepares wider masked parts and narrower exposed parts. Masked>Exposed areas in ELO. The ELO makes a mask having small windows. On the contrary the facet growth method based on the present invention employs narrow masks. The facet growth method prepares narrower masked parts and wider exposed parts. Masked<Exposed areas in facet growth. The facet growth method forms tiny, slim masks on an undersubstrate.

(b) The facet growth method is different from the ELO in the existence of polarity inversion region J. The ELO makes crystals on exposed parts and allows the crystals to ride upon the mask with the same orientation. The ELO is immune from the polarity inversion GaN crystals. For example, if an ELO crystal has {11-22} facets on the verges of masks, the ELO crystal steps on the mask and grows on the mask with maintaining {11-22} facets.

Polarity inversion does not take place in the ELO. The ELO-grown GaN is a single crystal as a whole. On the contrary, the facet growth of the present invention does not allow GaN crystals to step on masks but induces formation of beaks, which have inversion polarity, on facets. GaN grows on the beaks as seeds. Thus polarity inversion regions are born in the facet growth method. Discontinual interfaces are produced by the polarity inversion regions.

(c) The dislocation reduction growth direction is horizontal directions in the ELO. The ELO decreases dislocations by horizontally growing the crystal on the mask. The dislocation reduction growth direction is the vertical direction in the facet growth. Thick growth in the vertical direction gathers, arrests, annihilates and accommodates dislocations into defect accumulating regions H in the facet growth. The ELO and the facet growth are different in the defect-reducing growth directions.

(d) The ELO makes low defect density regions on masks. On-mask regions are low defect density crystals with high quality in the ELO. On exposed part, crystals with high defect density are grown in the ELO. On the contrary, the facet growth method based on the present invention produces low defect density GaN crystals with good quality on exposed parts. Masked parts produce low quality GaN crystals with high dislocation density in the facet growth. The ELO is entirely inverse to the facet growth at the point which of the masked parts and the exposed parts produces low dislocation density regions or high dislocation density regions.

### SUMMARY OF THE INVENTION

The present invention forms polarity inversion regions J on masks by preparing an undersubstrate, forming masks having a function of preventing GaN from epitaxial growing partially on the undersubstrate, preparing an undersubstrate with masked parts and exposed parts, supplying a Ga-material , an N-material and a carbon-material and growing GaN crystals on the masked undersubstrate in vapor phase. The gist of the present invention is that on-mask defect accumulating regions H are surely allotted to orientation (polarity) inversion regions J by carbon doping. Conventional vapor phase growth of GaN consists of two steps of (buffer layer formation)+(epitaxial growth). The present invention adds a step of orientation inversion region formation between the buffer layer formation and the epitaxial growth. The vapor phase GaN growth of the present invention consists of three steps of (buffer layer formation)+(carbon doping orientation inversion region formation) +(epitaxial growth).

Preferable candidates of undersubstrates are a sapphire (α-Al₂O₃) (0001) single crystal wafer, a silicon (Si) (111) single crystal wafer, a silicon carbide (SiC) (0001) single crystal wafer, a GaN single crystal wafer, a GaAs (111) single crystal wafer and so on. A GaN/sapphire complex wafer consisting a sapphire wafer and a thin GaN layer grown on the sapphire is another candidate for an undersubstrate. The GaN/sapphire wafer is called a “template.”

As shown in FIG. 7(1), a mask M, which is an assemble of masking stripes (M1) or masking dots (M2), is formed upon an undersubstrate U. The former (M1) is named a “stripemask” in short. The latter (M2) is named a “dotmask”. The materials of the mask are silicon dioxide (SiO₂), platinum (Pt), tungsten (W), silicon nitride (Si₃N₄) and so on. The thickness of the mask M is about 30 nm to 300 nm. The mask pattern is arbitrarily chosen. A dot mask (M2) pattern consists of plenty of isolated masking dots aligning regularly lengthwise and crosswise. A stripe mask (M1) pattern consists of plenty of linear masking stripes aligning at a constant pitch in parallel. The present invention allows both the dot mask (M2) and the stripe mask (M1). Formation of a mask divides the surface of the undersubstrate U into covered (masked) parts and exposed (unmasked) parts. The covered parts are narrow. The exposed parts are wide. This is a restriction deriving from the facet growth method.

Gallium nitride is grown at a low temperature on the undersubstrate. The low temperature grown GaN is a thin buffer layer of a thickness of about 30 nm to 200 nm. The temperature for growing the buffer layer is denoted by Tb. Tb=400° C. to 600° C. The buffer layer has a function of alleviating strain acting between the undersubstrate and the GaN layer.

The buffer layer is formed only on the exposed parts. The covered parts are still left uncovered with the buffer layer.

The gist of the present invention is carbon doping growth for promoting the formation of c-axis inversion regions J on the mask covered parts. GaN crystal is grown on the buffer/undersubstrate with supplying a Ga material, a nitrogen material and a carbon material. The covered parts are still uncovered with GaN. GaN crystals grow only on the exposed parts. The parts contacting with the mask become facets (F), as shown in FIG. 7(2).

The parts following the facet (F) is named low defect single crystal regions Z. Other parts lying far from the mask become C-plane growth regions Y, which have smooth C-plane surfaces.

Carbon doping generates inward extending beaks Q at middle points on slanting facets F rising from an end of the mask M (FIG. 7(3)). The beaks Q have an orientation with the c-axis rotating at 180 degrees to the surrounding regions. Namely a beak Q is a single crystal with inverse orientation. The beaks Q extend inward from the slanting facets F. Counterpart beaks Q come to contact above the mask M and join together, as exhibited in FIG. 7(4). GaN crystals further grow on the joint beaks Q as seeds. The crystals above the mask which grow on the beaks have inverse orientation with the c-axis reversed at 180 degrees to the c-axis of the surroundings. The GaN crystals grown on the beaks Q above the masks M are named “(c-axis) inversion regions J”. The inversion regions J further grow upward on the covered parts with maintaining constant sections which are slightly narrower than the covered parts or masks M (FIG. 7(5)). The inversion regions J attract dislocations from the surrounding regions and accumulate dislocations within the inversion regions J.

The HVPE method employs a Ga melt as a Ga material and supplies an HCl gas. HCl gas reacts with the Ga melt and synthesizes gallium chloride (GaCI). GaCl reacts with ammonia (NH₃) gas and makes gallium nitride (GaN). GaN is plied on the undersubstrate. The present invention aims to confirm the formation of inversion regions on masks by doping GaN with carbon (C). This invention uses hydrocarbon gases or solid carbon as materials of carbon. The HVPE growth is done under the atmospheric pressure (1 atm=0.1 MPa). When a hydrocarbon gas is used as a carbon material, the present invention should supply the hydrocarbon gas of a partial pressure between 1×10⁻⁴ atm (10Pa) and 5×10−² atm (5 kPa). For an early stage growth of forming inversion regions (H), the growing temperature should be 900° C. to 1100° C. Preferable range of the growing temperature is 990 ° C. to 1050° C. The growing speed is 50 μm/h to 100 μm/h. The time for making the orientation inversion regions is 0.5 hour to 2 hours.

Maintaining facets gathers dislocations on masks. On-mask regions in which many dislocations are accumulated are called defect accumulating regions H. The defect accumulating regions H take three different crystal structures. First alternative of H is an axis-inclining single crystal A having a slantingly upward c-axis. Second alternative of H is a polycrystal P. Third alternative is a c-axis inversion region J which has the c-axis reversed at 180 degrees to the c-axis of other regions Y and Z. Sometimes defect accumulating regions H are not generated on masks (case O). H has four alternatives O, P, A and J (H=0, P, A or J).

The present invention aims at making c-axis inversion regions J on masks as defect accumulating regions H. H=J is a purpose of the present invention. The on-mask regions H have a function of extracting dislocations existing on the surrounding portions under the facets and arresting the dislocations as defect accumulating regions. Since dislocations are eliminated from the surrounding portions, the surrounding portions become low defect density single crystal regions Z. The function of extracting and arresting dislocations is stronger in order of the polarity inversion J, the polycrystal P, c-axis slanting single crystal A and non-occurrence 0. The following inequality intuitively denotes the order of the power of O, A, P and J. non-occurrence O<c-axis slanting single crystal A<polycrystal P<polarity inversion J.

The polarity inversion J is the best for the defect accumulating region H. J is the best H. The present invention has searched the condition of assigning polarity (orientation) inversion regions J to the defect accumulating regions H and succeeded in making polarity inversion regions J on masks without fail.

The cathode luminescence (CL) can identify which is an on-mask defect accumulating region of A, P and J. A, P and J are discernible for the CL observation. Fluorescence microscope observation is available for discerning A, P and J. Human eye sight is incompetent, because GaN crystal is uniformly transparent.

Then thick GaN crystals are grown epitaxially on the masked undersubstrates with inversion regions J formed on the mask for a long time. The time of thick GaN crystal growth, which is contingent on the thickness of object GaN crystals, is several tens of hours, several hundreds of hours or several thousands of hours. The temperature of a thick GaN crystal is denoted by the second growth temperature Te for discerning from Tj which is the temperature of making the polarity inversion regions J. The second growth temperature has an appropriate range between 990° C. and 1200° C., i.e. Te=990° C. to 1200° C. The more preferable range is Te=1000° C. to 1200° C.

### ADVANTAGES OF THE INVENTION

Low defect density gallium nitride substrates with high quality have been required. The facet-growth method is promising, because the facet growth method can reduce dislocations by forming masks (dots or stripes) on an undersubstrate, growing GaN crystals in vapor phase, producing facets (pits or grooves) originating from the masks, making defect accumulating regions H on the masks, maintaining the facets and sweeping dislocations from the surrounding regions into the defect accumulating regions H. The defect accumulating region H has several candidates. The orientation inversion region J is the optimum for the defect accumulating region H. The inventors have found out that stable formation of the orientation inversion regions J having an inverse c-axis on the masks depends upon the crystal growth condition at an early stage of growth.

If the early stage growth condition is inappropriate, the defect accumulating regions H upon masks become polycrystal P or c-axis upward inclining single crystals A. The polycrystal P or c-axis upward inclining single crystals A have insufficient in attracting and arresting dislocations from neighboring crystal regions. It is strongly desired to establish the defect accumulating regions H on the masks as orientation inversion regions J.

The steps (3), (4), (5) and (6) mentioned above are early stages of forming the orientation inversion regions J (beaks Q). Generation of the beaks Q is so important. What is the essential condition to generate the beaks Q? This invention has found out that carbon doping at an early stage of growth induces the occurrence of beaks Q and orientation inversion regions J following the beaks Q.

The early stage growth time with carbon doping for preparing the beaks Q and inversion regions J is about 0.5 hour to 2 hours. At the end of the early growth stage with carbon doping, defect accumulating regions H which are orientation inversion regions J have made on masked parts, and low defect density single crystal regions Z have been made on exposed parts. Sometimes C-plane growth regions Y have been made at middles on exposed parts. Sometimes no C-plane growth regions Y are produced.

The present invention confirms the formation of the orientation inversion regions J by doping the growing GaN crystal with carbon. The formation of the orientation inversion regions J on the masked parts enables the defect accumulating regions H to attract, gather and arrest dislocations from the neighboring single crystal regions on the exposed parts. The neighboring regions become low defect density single crystal regions Z. Thus low defect density GaN crystals with high quality are obtained.

### DETAILED DESCRIPTION OF THE PREFERRED EMBODIMENTS

An HVPE method, MOCVD method, MOC. method and sublimation method are able to grow GaN crystals. The present invention employs the HVPE method for making orientation inversion regions on masks by carbon doping. MOCVD and MOC. methods use carbon-including Ga materials (metallorganic gases, e.g., trimethylgallium TMG, trimethylgallium TEG). It is still unclear whether the carbon included in the metallorganic gases in MOCVD and MOC. methods produces orientation inversion regions or not.

The present invention aims at GaN crystals grown by the HVPE (hydride Vapor Phase Epitaxy) method. The HVPE method uses a tall hot-wall furnace. The hot-wall HVPE furnace has a circular heater which is divided into several heater elements in the vertical direction for producing an arbitrary temperature distribution in the vertical direction. The furnace has a Ga-boat maintaining Ga metal in an upper space and a susceptor for supporting a specimen in a lower space.

The present invention grows GaN crystals in an HVPE furnace kept at the atmospheric pressure (1 atm=100 kPa). The furnace heats the Ga-boat at a temperature higher than 800° C. for melting Ga into a melt. The Ga-boat contains a Ga melt. Gas inlet pipes are furnished at the top of the furnace. A mixture of hydrogen and hydrochloride gases (H₂+HCl) is blown via a gas inlet pipe to the Ga melt in the Ga-boat. Reaction of HCl with Ga synthesizes gallium chloride (GaCl). GaCl is gaseous. GaCI gas falls and comes close to the heated susceptor and specimen. Another mixture of hydrogen and ammonia gases (H₂+NH₃) is blown via another gas inlet pipe in the vicinity of the heated susceptor. GaCl reacts with NH₃. GaN is synthesized. Synthesized GaN piles on the specimen.

The mask patterns formed on an undersubstrate are made of a material capable of preventing GaN from epitaxially growing thereon. Favorable mask materials are silicon dioxide (SiO₂), silicon nitride (SiN), platinum (Pt) and tungsten (W). Masks become seeds of defect accumulating regions H. An undersubstrate determines the orientation of GaN growing thereon. Directions of the masks determine the directions of facets aligning to the mask sides. Masks having sides satisfying a certain relation to the orientation of the undersubstrate should be prepared.

### Embodiment 1 Dependence upon first growth temperature Te

[1. Undersubstrate (U)]

Three kinds U1, U2 and U3 of undersubstrates are prepared. U1 is 2-inch diameter sapphire (Al₂O₃) single crystal substrates. U2 is 2-inch diameter gallium arsenide (GaAs) single crystal substrates. U3 is 2-inch diameter sapphire substrates covered with a 1.5 μm thick GaN epitaxially grown by an MOCVD method. The sapphire undersubstrates (U1) are C-plane (0001) surface wafers. The GaAs undersubstrates (U2) are (111)A-plane wafers. The GaN/sapphire undersubstrates (U3) have a mirror (0001) GaN surface. A GaN/sapphire wafer is sometimes called a “template”.

[2. Mask patterns (M)]

0.1 μm thick SiO₂ films are produced on the three kinds of undersubstrates U1, U2 and U3. Two kinds of patterns are formed by photolithography and etching. One is a stripe pattern (M1) having parallel mask stripes. The other is a dot pattern (M2) having isolated mask dots. The parts which are not covered with masks are named exposed parts. The parts which are covered with masks are named covered (masked) parts. GaN begins to grow on exposed parts.

(M1: Stripe Type Mask Pattern; FIG. 8)

FIG. 8(1) shows a stripe type mask pattern M1 having parallel linear mask stripes formed on an undersubstrate U. The stripes align in parallel at a common pitch p. The width of a mask stripe is s. The width of an exposed part is (p-s). GaN starts growth on exposed parts.

When GaN is grown on a masked undersubstrate by the facet growth method, linear defect accumulating regions (H) are produced upon the masks M as shown in FIG. 8(2). Low defect density single crystal regions Z are produced on exposed parts adjacent to the masks M. C-plane growth regions Y are sometimes produced at middles of the exposed parts and at other times no C-plane growth region Y appears.

A direction of extending stripes is determined to be parallel with <1-100>direction of the GaN crystal growing on the masked undersubstrate. The mask preparation precedes GaN growth. However, there is a definite relation between the undersubstrate orientation and GaN orientation grown on the undersubstrate. The directions of growing GaN crystal are deducible from the undersubstrate directions. A GaN crystal grown on an C-plane sapphire undersubstrate U1 has a 90 degree rotating orientation along the c-axis from the orientation of the sapphire C-plane undersubstrate U1. A GaN crystal grown on a GaAs(111) undersubstrate U2 has a similar orientation to the on-sapphire GaN with regard to three forehand numbers of Miller index. A GaN crystal grown on a GaN/sapphire undersubstrate (template) U3 has the same orientation as the GaN film. Determination of the extending direction of stripes with regard to the orientation of the undersubstrate succeeds in coinciding the mask extending direction with <1-100> direction of GaN crystal grown on the undersubstrate.

In the case of the GaN/sapphire undersubstrate (U3), the mask stripes should be determined in parallel to <1-100> direction of GaN. In the case of the (111) GaAs undersubstrate (U2), the mask stripes should be determined in parallel to <11-2> direction of GaAs. In the case of the sapphire undersubstrate (U1), the mask stripes should be determined in parallel to <11-20> direction of sapphire.

The stripemask pattern has parallel stripes with a width s of 30 μm, i.e. s=30 μm which are repeated at a pitch p of 300 μm, i.e. p=300 μm. Parallel exposed parts extend in the same direction. An exposed part has a width e of 270 μm, i.e. e=270 m. The pitch p is the sum of a masked part width s and an exposed part width e. p=e+s. The pitch is a distance from the middle of an exposed part to the middle of a neighboring expose part. The exposed:masked part ratio (e/s) is 9:1.

(M2: Dotmask pattern; FIG. 10)

A dotmask pattern M2 is composed of aligning dot trains with a discrepancy of half a pitch as shown in FIG. 10 (1). The pattern includes small round dots M placed at the corners of similar regular triangles which occupy the surface of an undersubstrate U without gap. Masked parts are narrower than exposed parts. Most of the parts are exposed parts.

Crystals start to grow on the exposed parts.

FIG. 10(2) shows a structure of a GaN crystal prepared by growing a GaN crystal on the dotmasked undersubstrate of FIG. 10(1) and eliminating the undersubstrate from the GaN crystal. Defect accumulating regions H are produced on mask dots M. Low defect density single crystal regions Z appear on exposed parts around the defect accumulating regions H.

A continual C-plane growth region Y occurs on an extra exposed part which is not covered with the low defect density single crystal regions Z.

In the case of a dotmask pattern M2, mask dots are arranged in symmetric spots.

The dot mask pattern is a set of dots lying on corner points of a plurality of regular triangles aligning two-dimensionally without gap. For example, a dotmask pattern with six fold rotation symmetry is employed. The direction of the trains of dots M is determined in parallel to GaN<1-100> direction. There is a definite relation between the undersubstrate orientation and the GaN orientation. Although GaN crystal is grown on an undersubstrate after forming the mask dots, the GaN<1-100> direction can be predetermined. In the case of a sapphire undersubstrate (U1), dot trains should be parallel to the sapphire<1 1-20> direction, since GaN<1-100>is generated to be parallel to sapphire <11-20>. In the case of a GaAs(111) undersubstrate (U2), dot trains should be parallel to the GaAs<11-2> direction.

A mask dot is circular. The diameter t of a dot is t=50 μm. The pitch p of a dotmask is p=300 μm. The pitch p is a distance between the nearest dot centers. The length f of an exposed part from a dot to a closest dot is f=250 μm. The unit regular triangle having three nearest dots has an area of 38971 μm². The dot has an area of 1963 m . 38971/1963=19.8.

The exposed:masked area ratio is about 1.9:1.

[3. Growth of forming buffer layers and orientation inversion regions J]

Embodiment 1 places M1, M2-masked undersubstrates U1, U2 and U3 (M1U1, M1U2, M1U3, M2U1, M2U2 and M2U3) on a susceptor in an HVPE furnace. At the initial stage, GaN buffer layers are grown for 15 minutes at a low temperature of about Tb=500° C. under an ammonia partial pressure P_{NH3}=0.2 atm (20 kPa) and a hydrochloride partial pressure P_{HCl}=2×10⁻³ atm (0.2 kPa). The thickness of the GaN buffer layers is 60 nm.

Then the specimens are heated up to an inversion region formation temperature TJ=1000° C. At Tj, orientation inversion regions J are grown on the masks and epitaxial crystals are grown on exposed parts for about one hour. Material gases are an (H₂+HCl) gas, an (H₂+NH₃) gas and a hydrocarbon gas. The hydrocarbon gas is either a methane gas or an ethane gas. The ammonia partial pressure is P_{NH3}=0.2 atm (20 kPa). The hydrochloride partial pressure is P_{HCl}=2×10⁻² atm (2 kPa). Some specimens are grown without supplying a hydrocarbon gas as comparison examples. After one hour growth, the specimens are cooled and are taken out of the furnace without further thick crystal growth. The optimum range of forming the orientation inversion regions J is Tj=970° C. to 1100° C. Appropriate time for inducing the orientation (polarity, c-axis) inversion regions J is 0.5 hour to 2 hours at an early stage of growth.

[4. Kinds of hydrocarbon gases and hydrocarbon partial pressure P_{HC}]

The present invention dopes a growing GaN crystal with carbon by supplying solid carbon or a hydrocarbon gas into a reaction furnace for preparing the orientation inversion regions J on masked parts. Methane (CH₄), ethane (C₂H₆), ethylene (C₂H₄), acetylene (C₂H₂) and other hydrocarbon gases are available for forming the inversion regions J.

Appropriate range of the hydrocarbon gas partial pressure is P_{HC}=1×10⁻⁴ atm (10 Pa) to P_{HC}=5×10⁻² atm (5 kPa). The following experiments adopt three kinds of hydrocarbon partial pressures.
(1) Methane gas (CH₄) P_{HC}8×10⁻³ atm(0.8 kPa).
(2) Ethane gas (C₂H₆) P_{HC}=8×10⁻³ atm(0.8 kPa).
(3) No hydrocarbon P_{HC}=0.
   [5. Crystal growth for inducing orientation inversion regions J]

Experiments have clarified the steps required to build 180 degree inverting c-axis regions J on masks.

FIGS.7(1), (2), (3), (4) and (5) demonstrate the steps of making the c-axis inversion regions J as defect accumulating regions H. FIG. 7(1) shows the formation of a stripemask on an undersubstrate U. Thought the figure shows only one mask, many identical masks M are formed on the undersubstrate as shown in FIG. 8(1). Instead of the stripemask, an arbitrary mask is available. The mask has a function of suppressing epitaxial growth of GaN. The masked undersubstrate is laid upon a susceptor in a reaction furnace, for example an HVPE furnace. GaN is grown on the masked undersubstrate MU in vapor phase. Initially GaN does not grown on the masks M. GaN starts to grow on exposed parts as shown in FIG. 7(2). Without stepping on the masks, GaN crystals pervade allover the exposed parts as films. Further growth increases the heights of the GaN crystals on the exposed parts. Slants starting from sides of the masks to tops of the GaN crystals are produced. The slants grow further without overstepping the masks. The slants are facets F having a definite inclination angle. The orientation of the facets F depends upon the direction of the masks. For example, the slants are {11-22} facets. There is no GaN crystal on the masks. A pair of facets F confront each other over a mask M.

The inventors have noticed a sign of building the orientation inversion regions J. Preceding the formation of orientation inversion regions J, rugged protrusions Q and Q appear at middle heights on the facets F. The protrusions Q are named beaks Q. Since the facets F and F confront each other, a pair of beaks Q and Q also confront each other (FIG. 7(3)). The beaks Q become seeds of the orientation inversion regions J. The orientation inversion regions J follow the beaks Q. Unless the beaks Q happen, no orientation inversion regions J occur. The beaks Q invite the orientation inversion regions J on masks. An upper surface of the beak Q inclines at an inclination angle between 25 degrees and 35 degrees to the horizontal plane. The beaks Q are single crystals having orientation 180 degrees inverting to the orientation of the neighboring facets F. Since the orientation is inverse in the beaks Q, the beaks Q are possible to become seeds of the orientation inversion regions J. The rugged beaks Q grow and extend further. Tips of the extending beaks Q and Q come in contact with each other. Then the beaks Q and Q are unified into a bridge as shown in FIG. 7(4). The bridge has the inversion orientation. The bridges are seeds of orientation inversion regions J.

As shown in FIG. 7(4), the space above the mask is covered with the unified beaks Q. The beaks Q have no contact with the masks. The beaks expand from intermediate heights of the facets F in the horizontal direction, meet with together and make a bridge. The both side facets F and F are bridged by the unified beaks Q. After the unification, crystals having the same orientation as the beaks Q grow on the unified beaks Q in the vertical direction. The beaks have c-axis inversion (orientation inversion) crystals. The crystals growing on the beaks Q become orientation inversion crystals J. As shown in FIG. 7(5), crystals with the same orientation as the beaks Q vertically grow on the beaks Q. The crystals which grow on the masked parts are defect accumulating regions H. The defect accumulating regions H become orientation inversion regions J. Higher crystals grow on both exposed parts. Closer inclining surfaces of the higher crystals are the facets F, which is shown by FIG. 7(4).

The on-exposed part crystals have plenty of dislocations generated at the interfaces between the undersubstrate and the growing crystals. Dislocations extend in the same direction as the growth direction. The facet growth method continues the growth without burying the facet pits or facet grooves.

Crystals on the facets grow in the direction vertical to the facets. Dislocations extend in the outward slanting direction which is in parallel with a normal standing on the facet. Dislocations extend toward the defect accumulating regions H on the masks. The dislocations attain at the defect accumulating regions H. The dislocations are arrested in the defect accumulating regions H. The once arrested dislocations never return to the facets F. Dislocation density in the crystals just below the facets F decreases. The crystals grown on the exposed parts below the facets are named low defect density single crystal regions Z.

Initially the regions have plenty of dislocations generated between the undersubstrate and the growing crystals. The facet growth extracts the dislocations out of the regions and transfers the dislocations into the defect accumulating regions H on the masks. The regions become low defect density. The orientation of the regions is determined to the relation with the undersubstrate. Thus the regions become low defect density single crystal regions Z. The interfaces between the low defect density single crystal regions Z and the defect accumulating regions H are grain boundaries K and K. The orientation is abruptly reversed at the grain boundaries K. The dislocations which have been once arrested in the defect accumulating regions H are not released again. The defect density of the neighboring regions Z becomes lower and lower with the progress of the facet growth.

The facet growth has been maintained until the end of the growth. Long time exclusion of dislocations from the exposed parts further enhances the quality of the low defect density single crystal regions Z due to the decrement of dislocations.

On the contrary sometimes the facet growth cannot produce inverse orientation regions J on masks. This invention has discovered that carbon doping is effective in producing the orientation inversion regions J on masks in the facet growth. The present invention makes orientation inversion regions J on masked parts at an early stage of growth by carbon doping, grows a thick GaN crystal film for a long time without carbon doping and makes low defect density GaN crystals of high quality. The main purpose of the present invention is production of orientation inversion regions J. Without further producing a thick GaN film, samples are cooled and are taken out of the furnace after the early stage of growth for examining whether the orientation inversion regions J appear on masked parts. All the samples have thicknesses of about 70 μm. The growth speed is about 70 μm/h.

[6. Observation of occurrence or non-occurrence of orientation inversion regions on masks]

[(1) In the case of Methane gas (CH₄); P_{HC}=8×10⁻³ atm (800 Pa)]
Undersubstrates=sapphire substrate (U1), GaAs substrate (U2), GaN/sapphire substrate(U3).
Mask pattern=stripe mask (M1), dot mask (M2).
Result of observation
M1; stripe mask; intermittent orientation inversion regions J appear like wavy lines on mask
stripes (U1, U2 and U3).
M2; dot mask; orientation inversion regions J occur on almost all of the mask dots (U1, U2 and U3).
[(2) In the case of Ethane gas (C₂H₆); P_{HC}=8×10⁻³ atm (800 Pa)]
Undersubstrates=sapphire substrate (U1), GaAs substrate (U2), GaN/sapphire substrate(U3).
Mask pattern=stripe mask (M1), dot mask (M2).
Result of observation
M1; stripe mask; intermittent orientation inversion regions J appear like wavy lines on mask stripes (U1, U2 and U3).
M2; dot mask; orientation inversion regions J occur on almost all of the mask dots (U1, U2 and U3).
[(3) In the case of non-hydrocarbon gas; P_{HC}=0]
Undersubstrates=sapphire substrate (U1), GaAs substrate (U2), GaN/sapphire substrate(U3).
Mask pattern=stripe mask (M1), dot mask (M2).
Result of observation
M1; stripe mask; few intermittent orientation inversion regions J appear on mask stripes (U1, U2 and U3).
M2; dot mask; orientation inversion regions J occur on few mask dots (U1, U2 and U3).

The results teach us that orientation inversion regions J occur intermittently on masks when no hydrocarbon gas is supplied. Supply of hydrocarbon gas promotes the occurrence of orientation inversion regions J on masks. Methane and ethane are equivalently suitable for a carbon doping gas. 800 Pa of hydrocarbon partial pressure develops the orientation inversion regions J on masks but is still insufficient for orientation inversion regions J to occupy all the masks. Further higher hydrocarbon (CH₄, C₂H₆, etc.) partial pressure is required of orientation inversion regions in order to prevail on all the masks.

### Embodiment 2 (Solid Carbon)

Embodiment 2 grows GaN crystals on SiO₂ masked (M1 and M2) C-plane sapphire undersubstrates (U1), GaAs undersubstrates (U2) and GaN/sapphire undersubstrates in the same furnace as Embodiment 1 for 60 minutes with a supply of carbon. Embodiment 2 differs from Embodiment 1 in the method of carbon supply. Instead of supplying hydrocarbon gases, Embodiment 2 uses solid carbon. A carbon plate is placed at a higher temperature part set at an upstream of the growth part (susceptor) in the HVPE furnace. The other conditions are similar to Embodiment 1.

Undersubstrates (U1, U2 and U3) with stripe and dot masks (M1; M2) are put on the susceptor in the furnace.

At an early stage, GaN buffer layers are grown for 15 minutes on the M1, M2-masked undersubstrates (U1, U2 and U3) at a low temperature of about 500° C. (Tb=500° C.) under an ammonia partial pressure P_{NH3}=0.2 atm (20 kPa) and a P_{HCl} partial pressure P_{HCl}=2×10⁻³ atm (0.2 kPa). The thickness of the GaN buffer layers is about 60 nm.

The temperature is raised up to an inversion region generating temperature Tj=1000° C. Orientation inversion regions and epitaxial growth regions are grown on masked parts and exposed parts respectively for about one hour at 1000° C. under P_{NH3}0.2 atm (20 kPa) and P_{HCl}=2×10⁻² atm (2 kPa). Carbon is supplied from the carbon plate placed between the Ga-boat and the susceptor. After one hour growth, samples are cooled and taken out of the furnace without further growth for examining occurrence or non-occurrence of orientation inversion regions.
Results of observation
Undersubstrates; sapphire (U1), GaAs (U2), GaN/sapphire (U3)
GaN film thicknesses: 70 μm
M1(stripe mask): intermittent orientation inversion regions J occur like wave lines on mask stripe.
M2(dot mask): Orientation inversion regions J appear on almost all the mask dots.

It is confirmed that Embodiment 2 which has a carbon plate as a carbon source can produce orientation inversion regions J on masked parts. Similar results are observed on the GaN films grown on the sapphire (U1), GaAs (U2) and GaN/sapphire undersubstrates. There is no difference in the kinds of undersubstrates. The GaN is transparent without being colored black or yellow.

After the growth, the carbon plate placed in the furnace is taken out. The weight of the carbon plate is measured. The weight of the carbon plate has been reduced. The carrier gas is hydrogen (H₂). An equivalent partial pressure of hydrocarbon is calculated on the assumption that all the loss of weight of carbon would be converted into methane gas CH₄. The methane partial pressure is calculated to be P_{HC}=1×10⁻² atm (1 kPa) by taking account of the gas flow velocity. P_{HC}=1 kPa is safely included within the scope of 10 Pa to 5 kPa.

Embodiment 2 teaches us that solid carbon has the same effect in making orientation inversion regions as hydrocarbon gases. Instead of supplying gaseous hydrocarbons, solid carbon is also available.

When a carbon plate is placed in the furnace, the tens hour to thousands hour growing thick GaN crystals following the 0.5 hour to 2 hour long formation of the orientation inversion regions J are also doped with carbon. When carbon containing GaN crystals are undesirable, the solid carbon method is inappropriate.

### Embodiment 3 (Relation Between Hydrocarbon Partial Pressure P_{HC} and Formation of Orientation Inversion Regions J

Embodiment 3 examines the dependence of formation of orientation inversion regions J upon hydrocarbon partial pressure by varying the partial pressure (flow rate) of gaseous carbon material similar to Embodiment 1. Embodiment 3 uses the same HVPE furnace as Embodiment 1. Embodiment 3 employs GaAs(111) A-plane wafers (U2) as undersubstrates. A dot-mask (M2) is formed on a GaAs(111) undersubstrate (U2). This is a dotmasked GaAs undersubstrate (M2U2). A stripe mask (M1) is formed on another GaAs(111) undersubstrate (U2). This is a stripemasked GaAs undersubstrate (M1U2).

Buffer layers and orientation inversion regions J are produced upon two kinds of undersubstrates (M1 U2, M2U2). Change of the inversion region formation is examined by varying the supply of hydrocarbon gases.

Embodiment 3 places the above specimens on a susceptor in an HVPE furnace.

GaN buffer layers are grown for 15 minutes at a low temperature of about 500° C.(Tb) under a NH₃ partial pressure of P_{NH3}=0.2 atm (20 kPa) and an HCl partial pressure of P_{HCl}=2×10⁻³ atm (0.2 kPa). The ammonia/hydrochloride ratio is P_{NH3}/P_{HCl}=100. The thickness of the GaN buffer layer is about 60 nm.

The specimens are further heated up to a temperature of Tj=1000° C. for inducing orientation inversion regions J by carbon doping, i.e. by supplying methane gas. The NH₃ partial pressure is P_{NH3}=0.2 atm (20 kPa). The HCl partial pressure is P_{HCl}=2×10⁻² atm (2 kPa). The ammonia/hydrochloride ratio is P_{NH3}/P_{HCl}=10.

There is a definite relation between the partial pressure of a gas and the flow of the gas. Mass flow controllers, etc. control the flows of gases. Embodiment 3 maintains the whole pressure of the HVPE furnace at 1 atm (0.1 MPa: the atmospheric pressure). The sum of the gas flows (total flow) is known. The partial pressures of each gas can be calculated from the flow of the gas by dividing the gas flow by the total flow and multiplying the quotient by the total pressure. The partial pressures of NH₃, HCl and CH₄ are values calculated from the measured flows of NH₃, HCl and CH₄, respectively

Embodiment 3 gives 60 minutes to the HVPE furnace for forming orientation inversion regions J on growing specimens. The thickness of the grown GaN layer is about 70 μm. The growing speed is about 70 μm/h. Embodiment 3 assigns seven different values to the methane partial pressure P_{CH4}.
(1) P_{CH4}1=5×10⁵ atm (5 Pa)
(2) P_{CH4}2=1×10⁻⁴ atm (10 Pa)
(3) P_{CH4}3=1×10⁻³ atm (10 kPa)
(4) P_{CH4}4=5×10⁻³ atm (500 Pa)
(5) P_{CH4}5=1×10⁻² atm (1 kPa)
(6) P_{CH4}6=5×10⁻² atm (5 kPa)
(7) P_{CH4}7=1×10⁻¹ atm (10 kPa)

The specimens are cooled and taken out of the furnace. The specimens are observed by a substantial microscope and a scanning electron microscope (SEM) for examining how the occurrence of the orientation inversion regions J depends upon the methane partial pressure P_{CH4}.
(1) In the case of P_{CH4}1=5×10⁻⁵ atm (5 Pa)
Result of observation:
M1: Stripe mask: Intermittent inversion regions appear on the mask stripes.
M2: Dot mask: Intermittent inversion regions are generated upon few of the mask dots.
(2) In the case of P_{CH4}2=1×10⁻⁴ atm (10 Pa)
Result of observation:
M1: Stripe mask: Intermittent wavy inversion regions occur on the mask stripes.
M2: Dot mask: Inversion regions are generated upon most of the mask dots.
(3) In the case of P_{CH4}3=1×10³ atm (100 Pa)
Result of observation:
M1: Stripe mask: Continual inversion regions lie on all the mask stripes.
M2: Dot mask: Inversion regions are generated upon all of the mask dots.
(4) In the case of P_{CH4}4=5×10⁻³ atm (500 Pa)
Result of observation:
M1: Stripe mask: Continual inversion regions lie on the mask stripes.
M2: Dot mask: Inversion regions are generated upon all the mask dots.
(5) In the case of P_{CH4}5=1×10⁻² atm (1 kPa)
Result of observation
M1: Stripe mask: Continual inversion regions lie on the mask stripes.
M2: Dot mask: Inversion regions are generated upon all the mask dots.
(6) In the case of P_{CH4}6=5×10−2 atm (5 kPa)
Result of observation
M1: Stripe mask: Crystal is colored black. Wavy inversion regions intermittently lie on the mask stripes.
M2: Dot mask: Crystal is colored black. Inversion regions are generated upon some of the mask dots.
(7) In the case of P_{CH4}7=1×10⁻¹ atm (10 kPa)
Result of observation
M1: Stripe mask: Crystal is turned black. Cracks occur on the whole surface.
M2: Dot mask: Crystal is turned black. Cracks occur on the whole surface.

P_{CH4}1=5 Pa, which makes intermittent inversion regions on masks, is inappropriate. P_{CH4}7=10 kPa, which colors the whole crystal black, is inappropriate. Appropriate range of methane partial pressures for the inversion region formation on masks is from P_{CH4}2=1×10⁴ atm (10 Pa) to P_{CH4}6=5×10₋₂ atm (5 kPa).

The scope of P_{CH4} capable of inducing inversion regions on all masks and avoiding black colored crystals is P_{CH4}3=1×10⁻³ atm (100 Pa) to P_{CH4}5=1×10⁻² atm (1 kPa). Namely the formation of inversion regions requires a methane partial pressure P_{CH4} in a range between 10 Pa and 5 kPa. P_{CH4} has a more preferable range between 100 Pa and 1 kPa.

The above result is obtained in the case of supplying gaseous hydrocarbon for carbon doping. A similar effect is realized also in the case of placing solid carbon in the furnace for reacting with hydrogen gas to produce hydrocarbon gases at a partial pressure within the above scope.

### Embodiment 4 (inversion region formation, thick GaN growth, grinding, polishing, slicing to wafers)

Embodiment 4 examines the wafers produced by forming buffer layers, making orientation inversion regions J, growing thick GaN crystals, slicing the GaN crystals into wafers, grinding the wafers and polishing the wafers.

Masked undersubstrates (M1U1, M2U1) are prepared by forming a stripe mask (M1) and a dot mask (M2) on sapphire undersubstrates (U1). Embodiment 4 places the masked undersubstrates (M1U1,M2U1) on a susceptor in an HVPE furnace and forms buffer layers on the masked undersubstrates at a low temperature Tb=500° C. under an NH₃ partial pressure 0.2 atm (20 kPa) and an HCl partial pressure 2×10⁻³ atm(200 Pa). The growth time is 15 minutes. The thickness of the buffer layer is 60 nm.

The temperature of the susceptor is raised to Tj=1000° C. Embodiment 4 grows epitaxial GaN layers on the buffer/masked undersubstrates (M1U1, M2U1) at 1000° C. under an NH₃ partial pressure of 0.2 atm (20 kPa), an HCl partial pressure of 3×10² atm(3 kPa) and a CH₄ partial pressure of 8×10⁻³ atm (800 Pa) for 15 hours, cools specimens consisting of grown GaN crystals and masked undersubstrates and takes the specimens out of the furnace.

Embodiment 4 obtains thick GaN crystals with about 15 mm thickness on the undersubstrates (M1U1, M2U1). The growth speed is 100 μm/h. Surfaces of the GaN crystals are observed by an optical microscope and a scanning electron microscope (SEM).

FIG. 6(1) shows a perspective view of a part of a specimen (GaN/M1U1) of growing GaN crystal on the stripe-masked undersubstrate (M1U1). FIG. 6(2) shows a perspective view of a part of another specimen (GaN/M2U1) of growing GaN crystal on the dot-masked undersubstrate (M2U1). The stripe mask (M1) makes a groove-structured GaN crystal having repetitions of parallel hills and valleys. It is observed that Valley bottoms coincide with the mask stripes. The dot mask (M2) makes a GaN crystal having a flat surface and many isolated pits distributing on the flat surface. It is observed that the pit bottoms coincide with the mask dots. It is confirmed that lower inclination angle facets are formed at the bottoms of the pits and valleys. It is identified that the lower inclination angle facets should be {11-2-6} planes having an inverse c-axis. There are other steeper facets at intermediate regions in the pits or the grooves. It is assumed that the steeper facets should be {11-22} planes. This means the occurrence of orientation inversion regions J at the positions of the mask stripes or dots.

The sapphire undersubstrates (U1) are eliminated by grinding. Freestanding GaN crystals are obtained. Surfaces are ground and polished. Smooth GaN mirror wafers are obtained. The GaN wafers are transparent. Structures are indiscernible for human eye sight. The smooth surfaces of the GaN wafers are examined by an optical microscope and cathode luminescence (CL). Parallel linear grooves of a width of 20 μm regularly aligning at a pitch of 300 μm are observed in the stripemasked (M1) specimen. The grooves are defect accumulating regions H. The grooves derive from the occurrence of {11-2-6} planes. The existence of {11-2-6} planes signifies that the defect accumulating regions H are orientation inversion regions J. The GaN wafer has the HZYZHZYZ structure as shown in FIG. 8(2).

The dotmasked (M2) specimen reveals concavities with a 30 μm to 40 μm diameter arranged at a pitch of 300 μm at spots having six fold rotation symmetry. The concavities correspond to the positions of the mask dots. FIG. 10(2) shows a CL image of a part of the GaN crystal produced on the dotmask (M2). The crystal has a concentric structure consisting of a defect accumulating region H, a low defect density single crystal region Z and a C-plane growth region Y. Comparison FIG. 10(2) with FIG. 10(1) confirms that the defect accumulating regions H are generated on the mask dots and the low defect density single crystal regions Z and the C-plane growth region Y are produced on the exposed parts.

CL observation shows a threading dislocation appearing on the surface as a dark spot. Etch pit density (EPD), which is a density of the threading dislocations, is measured by counting dark spots in a definite area on the CL image. Defect accumulating regions H have a high EPD of 10⁷ cm₋₂ to 10⁸ cm⁻². Low defect density single crystal regions Z and C-plane growth regions Y have low EPDs of about 1×10⁵ cm⁻². It is confirmed that wide low defect density single crystal regions Z with a low EPD are generated. The GaN crystals made in Embodiment 4 are inhomogeneous GaN substrates containing Zs, Y and Hs. But the positions and areas of Zs, Y and Hs are clearly predetermined in the GaN substrates. The GaN substrates of the present invention enable to provide low defect density GaN substrate wafers for making blue/violet laser devices enjoying high quality.

Elements contained in the GaN crystals grown by Embodiment 4 are measured by SIMS (Secondary Ion Mass Spectroscopy) for examining whether carbon atoms are absorbed in the grown GaN substrates or not.

The SIMS measurement shows that the orientation inversion regions J (defect accumulating regions H) on the masks have a higher carbon concentration of about 1×10¹⁷ cm⁻³.

The low defect density single crystal regions Z have a lower carbon concentration of 5×10¹⁶ cm⁻³ in Embodiment 4. The C-plane growth region Y has a still higher carbon concentration of 4×10¹⁸ cm⁻³. It is confirmed that carbon is really doped into the gallium nitride crystal. It turns out that the carbon doping efficiency has a strong dependence upon the growing planes. Carbon concentrations in Zs, Hs and Y satisfy an inequality Z<H<Y in Embodiment 4.

Further many experiments have been repeated. Examinations of results of the experiments clarify that carbon concentrations in the inversion regions J (defect accumulating regions H) are less than 10¹⁸ cm⁻³ (H<10¹⁸ cm⁻³). The low defect single crystal regions Z, which have been grown with maintaining facets, have carbon concentrations less than 10¹⁸ cm⁻³ (Z<10¹⁸ cm⁻³). The C-plane growth region Y, which has been grown with a flat C-plane, has a carbon concentration between 10¹⁶ cm⁻³ and 10²⁰ cm⁻³ (10¹⁶cm⁻³≦Y≦10²⁰ cm⁻³). The C-plane growth region Y has the highest carbon concentration among Y, Zs and Hs. Carbon ratios Y/H and Y/Z are 10¹ to 10₅ (10_{1 ≦Y/H≦}10⁵, 10¹≦Y/Z ≦10₅). The carbon ratio Y/H means a quotient of the carbon concentration of the C-plane region Y divided by the carbon concentration in the defect accumulating regions H. The carbon ratio Y/Z means a quotient of the carbon concentration of the C-plane region Y divided by the carbon concentration in the low defect single crystal regions Z.

The C-plane growth regions Y have the highest carbon concentrations. But electric conductivity is the lowest in the C-plane growth regions Y among Ys, Hs and Zs. It is assumed that carbon does not generate n-type carriers (free electrons) as an n-type dopant.

### BRIEF DESCRIPTION OF THE DRAWINGS

FIG. 1(a) is a perspective view of a facet pit appearing on a growing surface at a starting stage of growth for demonstrating the facet growth method proposed (2) by Japanese Patent Laying Open No.2001-102307 which makes hexagonal facet pits on a growing surface, grows GaN without burying the facet pits, concentrates dislocations at boundaries of the facets and sweeps dislocations into bottoms of the facet pits.

FIG. 1(b) is a perspective view of a facet pit appearing on a growing surface at a later stage of growth for demonstrating the facet growth method proposed by (2) Japanese Patent Laying Open No.2001-102307 which makes hexagonal facet pits on a growing surface, grows GaN without burying the facet pits, concentrates dislocations at boundaries of the facets and sweeps dislocations into bottoms of the facet pits.

FIG. 2 is a plan view of a facet pit appearing on a growing surface for demonstrating the facet growth method proposed by (2) Japanese Patent Laying Open No.2001-102307 which makes hexagonal facet pits on a growing surface, grows GaN without burying the facet pits, concentrates dislocations at boundaries of the facets and gathers dislocations at bottoms of the facet pits.

FIG. 3(1) is a sectional view of a facet pit appearing on a growing surface for demonstrating the facet growth method proposed by (2) Japanese Patent Laying Open No.2001-102307 which makes hexagonal facet pits on a growing surface, grows GaN without burying the facet pits, concentrates dislocations at boundaries of the facets, gathers dislocations at bottoms of the facet pits and makes a dislocation bundle. FIG. 3(2) shows a sectional view of a facet pit with a hazy dispersion of dislocations escaping from the pit.

FIG. 4(1) is a sectional view of a pit or V-groove at an early stage for demonstrating the mask-facet growth method proposed by (3) Japanese Patent Laying Open No. 2003-165799 and (4) Japanese Patent Laying Open No. 2003-183100 which make dislocation-attractive defect accumulating regions (H) on masked parts, make low defect density single crystal regions (Z) under facets, produce C-plane growth regions (Y) under C-plane surfaces and maintain dislocations in the defect accumulating regions (H). FIG. 4(2) shows a sectional view of the pit or V-grooves at a later stage for showing dislocations being arrested in the defect accumulating regions (H) without being dispersed till the end of the growth.

FIG. 5(1) is a section of an undersubstrate (U) and a mask (M) formed on the undersubstrate (U) at a start of the facet growth method. FIG. 5(2) is a section of the undersubstrate (U), the mask (M) and GaN crystals at a later stage for showing the masked parts prohibiting GaN growth, slanting facets starting from ends of the mask and rising to the C-plane surface. FIG. 5(3) is a section of the undersubstrate (U), the mask (M) and GaN crystals at a further later stage for showing the occurrence of a defect accumulating region (H) on the masked parts and appearance of two step facets in the pit or the valley.

FIG. 6(1) is a perspective view of a prism-roofed GaN crystal produced by a facet growth method of forming mask stripes on an undersubstrate (U), growing GaN in vapor phase, producing facet valleys and making defect accumulating regions (H) on the stripe-covered parts. FIG. 6(2) is a perspective view of a pit-roofed GaN crystal produced by a facet growth method of forming mask dots on an undersubstrate (U), growing GaN in vapor phase, producing facet facet pits and making defect accumulating regions on the dot-covered parts.

FIG. 7(1) is a section of an undersubstrate (U) and a mask (M). FIG. 7(2) is a section of the undersubstrate (U), the mask (M) and GaN crystals grown on exposed parts, and facets (F) starting from sides of the mask. FIG. 7.(3) is a sectional view for showing beaks (Q) appearing on slants of the facets. FIG. 7(4) is a sectional view for showing the beaks (Q) meeting together above the mask and being unified. FIG. 7(5) is a section for showing GaN crystals growing on the unified beaks with the same orientation as the beaks (Q).

FIG. 8(1) is a plan view of an undersubstrate (U) and linear parallel mask stripes (M) formed at a pitch p on the undersubstrate. FIG. 8(2) is a CL (cathode luminescence) image of a facet-grown, sliced and polished GaN crystal having parallel low dislocation single crystal regions (Z), C-plane growth regions (Y) and defect accumulating regions (H).

FIG. 9(1) is a section of an undersubstrate (U). FIG. 9(2) is a section of the undersubstrate (U) and mask stripes (M) in the strip-mask facet growth. FIG. 9(3) is a section of the undersubstrate (U), the mask stripes (M) and a thick grown GaN crystal on the masked undersubstrate with defect accumulating regions (H) on the mask stripes, low defect single crystal regions (Z) below facets on exposed parts and C-growth regions (Y) below C-plane surfaces on the expose parts. FIG. 9(4) is a CL image of a flat HZYZHZYZH structured GaN crystal produced by eliminating the undersubstrate from the GaN crystal, grinding the separated GaN crystal and polishing the GaN crystal. FIG. 9(5) is a CL image of a flat HZHZH structured GaN crystal without C-plane growth regions (Y).

FIG. 10(1) is a plan view of an undersubstrate (U) and isolated mask dots formed at a pit p with six-fold symmetry on the undersubstrate (U) in the dot-mask facet growth. FIG. 10(2) is a CL image of a flat HZY hexagonal symmetric GaN crystal produced by eliminating the undersubstrate from the GaN crystal, grinding the separated GaN crystal and polishing the GaN crystal.

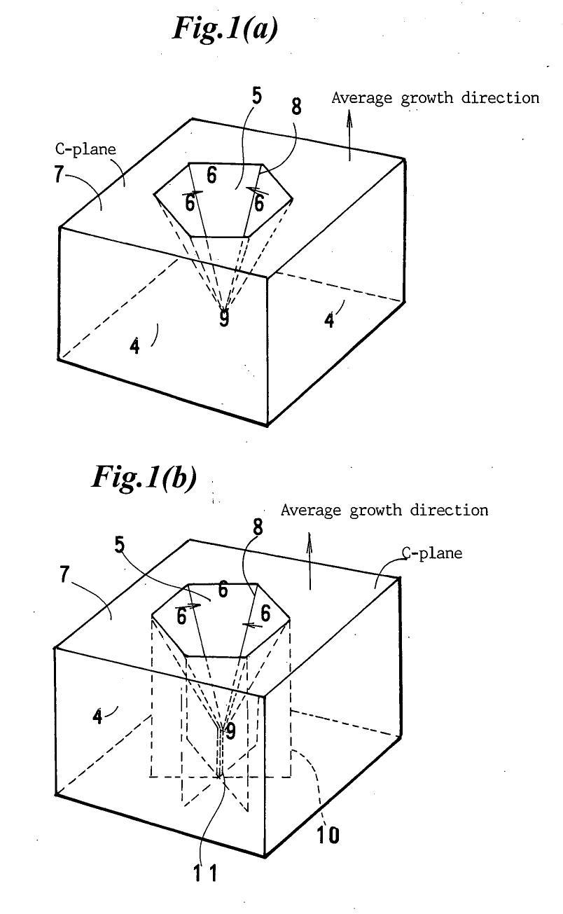

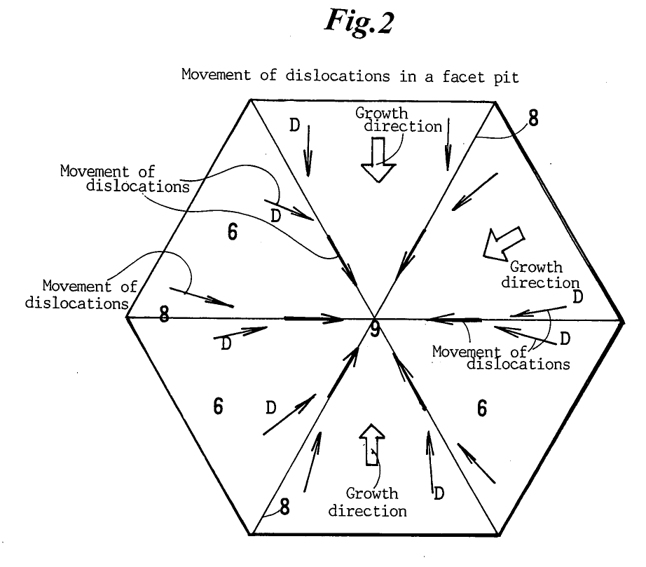

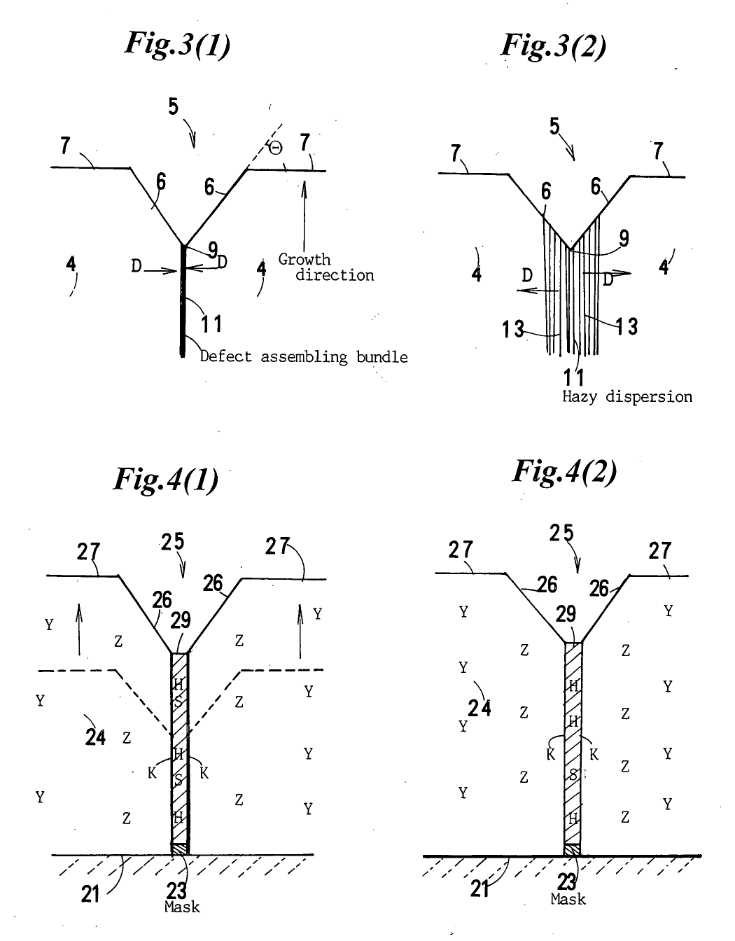

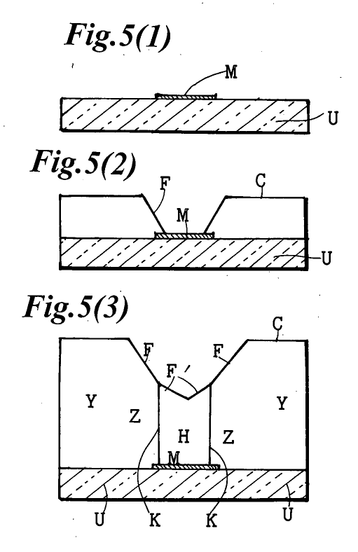

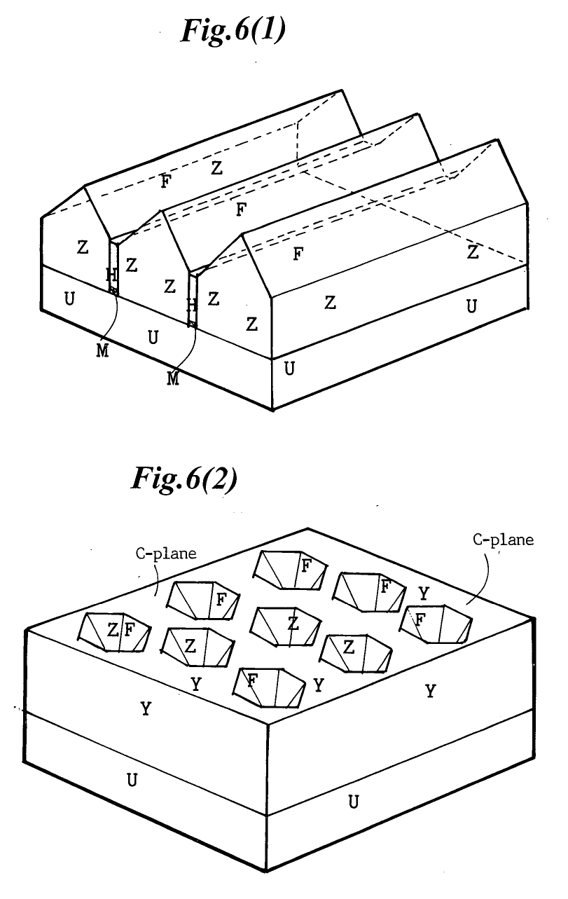

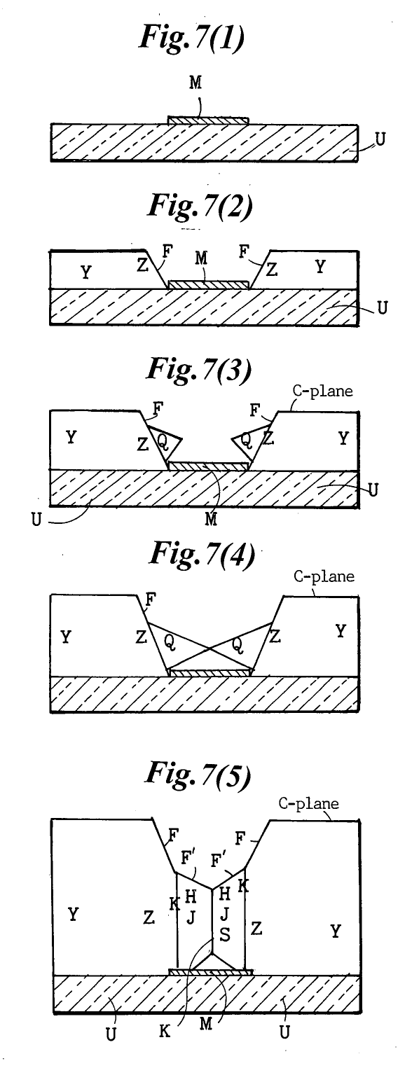

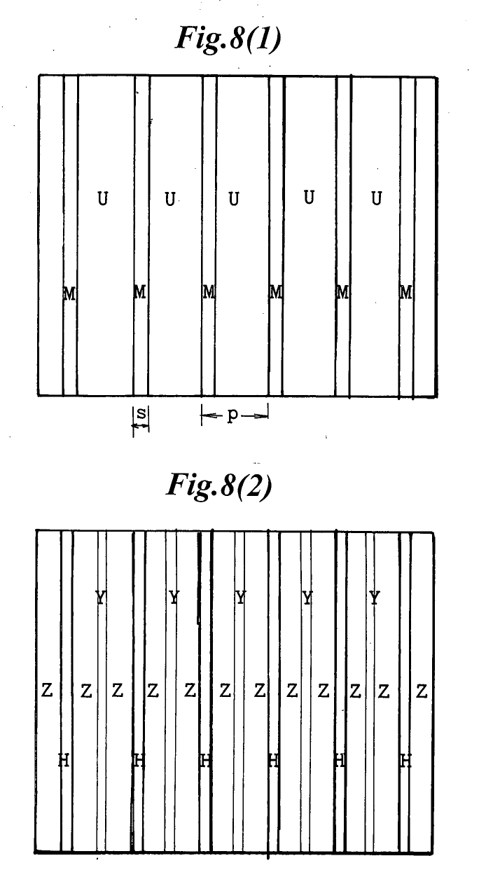

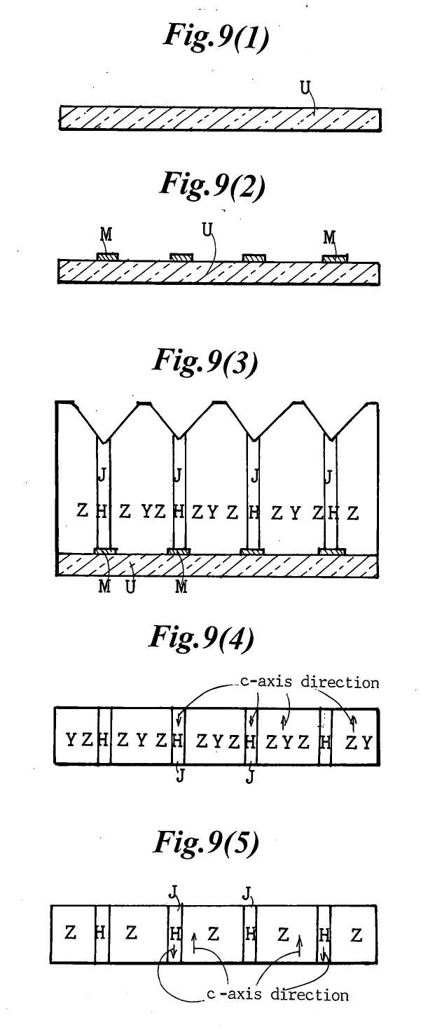

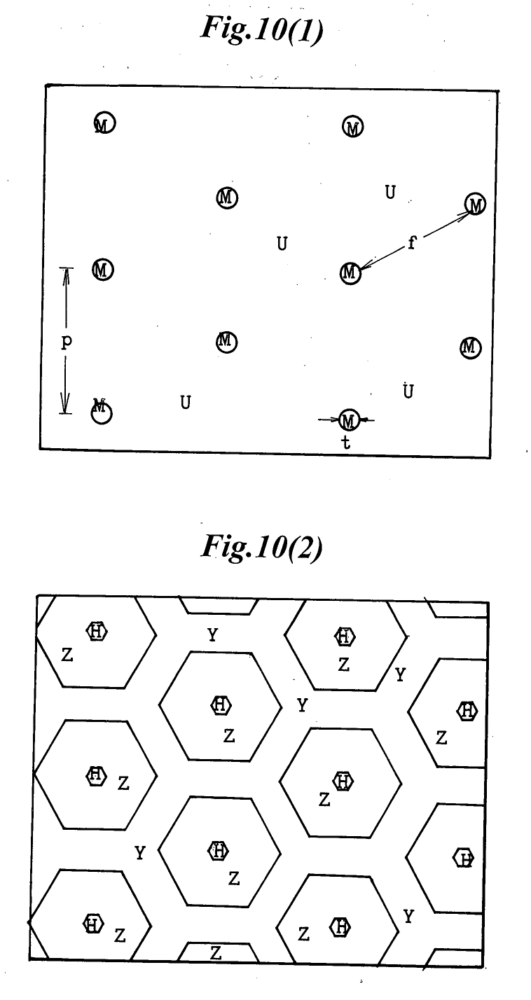

What we claim is:

1. A method of growing a gallium nitride crystal comprising the steps of:
preparing an undersubstrate;
forming masks which suppresses gallium nitride from epitaxially growing on the undersubstrate;
making masked parts and exposed parts on the undersubstrate;
placing the masked undersubstrate in a reaction furnace;
growing gallium nitride on the masked undersubstrate in vapor phase;
making pits of facets or grooves of facets with bottoms which correspond to the masks;
doping growing gallium nitride with carbon for 0.5 hour to 2 hours at least at an initial stage of growth;
growing epitaxially low defect density single crystal regions Z having a polarity under the facets on the exposed parts of the undersubstrate till an end of growth;
growing epitaxially C-plane growth regions Y under C-planes having the same polarity on the exposed parts of the undersubstrate till the end of growth;
inducing beaks on the facets having a polarity different by 180 degrees from the polarity of the gallium nitride single crystals Z and Y on the exposed parts by carbon doping; and
maintaining the facet pits or facet grooves till the end of growth.

2. A method of growing a gallium nitride crystal comprising the steps of:
preparing an undersubstrate;
forming masks which suppresses gallium nitride from epitaxially growing on the undersubstrate;
making masked parts and exposed parts on the undersubstrate;
placing the masked undersubstrate in a reaction furnace;
growing gallium nitride on the masked undersubstrate in vapor phase;
making pits of facets or grooves of facets with bottoms which correspond to the masks;
doping growing gallium nitride with carbon for 0.5 hour to 2 hours at least at an initial stage of growth;
growing epitaxially low defect density single crystal regions Z having a polarity under the facets on the exposed parts of the undersubstrate till an end of growth;
growing epitaxially C-plane growth regions Y under C-planes having the same polarity on the exposed parts of the undersubstrate till the end of growth;
inducing beaks on the facets having a polarity different by 180 degrees from the polarity of the gallium nitride single crystals Z and Y on the exposed parts by carbon doping;
expanding the beaks from the facets above the masks;
unifying the beaks into bridges having a polarity different by 180 degrees from the polarity of the gallium nitride single crystals Z and Y on the exposed parts;
making polarity inversion gallium nitride single crystal regions J on the bridges above the masks;
covering the masks the with the polarity inversion gallium nitride single crystal regions J having a polarity different by 180 degrees from the polarity of the gallium nitride single crystals Z and Y on the exposed parts; and
maintaining the facet pits or facet grooves till the end of growth.

3. The method as claimed in claim 2, wherein the <0001> direction of the single crystal on the exposed parts is equal to <000-1> direction ofthe polarity inversion gallium nitride single crystals on the masks.

4. The method as claimed in claim 2, wherein gallium nitride buffer layers with a thickness less than 200 nm are grown on the undersubstrate with the masks at a low temperature between 400° C. and 600° C. before epitaxially growing gallium nitride single crystals.

5. The method as claimed in claim 4, wherein the temperature of growing epitaxially gallium nitride single crystals is 900° C. to 1100° C.

6. The method as claimed in claim 2, wherein the undersubstrate is a sapphire wafer, a Si wafer, a SiC wafer, a GaN wafer, a GaAs wafer or a foreign material wafer coated with a GaN thin layer.

7. The method as claimed in claim 2, wherein the growth in vapor phase is HVPE (hydride vapor phase epitaxy).

8. The method as claimed in claim 2, wherein a hydrocarbon gas is supplied into the reaction furnace for doping growing gallium nitride with carbon.

9. The method as claimed in claim 8, wherein the hydrocarbon gas is CH₄, C₂H₆ or C₂H_{4.}

10. The method as claimed in claim 8, wherein the hydrocarbon gas has a partial pressure from 1×10⁻⁴ atm (10 Pa) to 5×10⁻² atm (5 kPa).

11. The method as claimed in claim 2, wherein solid carbon is laid in the reaction furnace for inducing a reaction of carbon with HCl gas, synthesizing hydrocarbon gases and doping growing gallium nitride with carbon.

12. The method as claimed in claim 11, wherein the synthesized hydrocarbon has a partial pressure from 1×10⁻⁴ atm (10 Pa) to 5×10⁻² atm (5 kPa).

13. A gallium nitride substrate comprising:
low defect density single crystal regions Z being grown under facets on exposed parts in a facet growth method and having carbon concentration less than 10¹⁸ cm⁻³;
polarization inversion regions J being grown on masks in the facet growth method and having a carbon concentration less than 10¹⁸ cm⁻³;
C-plane growth regions Y being grown under C-planes on exposed parts and having a carbon concentration of 10¹⁶ cm⁻³ to 10²⁰ cm⁻³; and
carbon concentration ratios Y/J and Y/Z being 10¹ to 10⁵.

14. The gallium nitride substrate as claimed in claim 13, wherein the low defect density single crystal regions Z have grown under {11-22} facets.

15. The gallium nitride substrate as claimed in claim 13, wherein the polarity inversion regions J have grown under {11-2-6} facets.
